(19) United States
(12) Patent Application Publication
(10) Pub. No.: US 2009/0315179 A1
(43) Pub. Date: Dec. 24, 2009

(54) SEMICONDUCTOR DEVICE HAVING SOLDER BUMPS PROTRUDING BEYOND INSULATING FILMS

(76) Inventors: Hiromi SHIGIHARA, Hitachinaka (JP); Hisao Shigihara, Hitachinaka (JP); Akira Yajima, Tsuchiura (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/547,980

(22) Filed: Aug. 26, 2009

Related U.S. Application Data
(62) Division of application No. 11/300,308, filed on Dec. 15, 2005.

(30) Foreign Application Priority Data
Dec. 17, 2004 (JP) 2004-366029

(51) Int. Cl. H01L 23/498

(52) U.S. Cl. 257/737; 257/E23.068

(57) ABSTRACT

A semiconductor device having projection electrodes with a narrow pad pitch, and a method of forming such semiconductor device, are provided. On a semiconductor wafer, a polyimide film, which does not cover each of a plurality of lands, is prepared between the respective lands which adjoin each other among the plurality of lands on the main surface of the semiconductor wafer. A soldering paste material is applied by a printing method, via a mask for printing, on each of a plurality of lands after polyimide film formation, and a solder bump is formed by performing heat curing of the soldering paste material after removing the mask for printing. The solder bump can be provided without generating an electric short circuit between bumps even in the case of a narrow pad pitch.

### CROSS-REFERENCE TO RELATED APPLICATION

This application is a Divisional application of application Ser. No. 11/300,308 filed Dec. 15, 2005, the contents of which are incorporated herein by reference in their entirety.

The present application claims priority from Japanese patent application No. 2004-366029 filed on Dec. 17, 2004, the content of which is hereby incorporated by reference into this application.

### 1. FIELD OF THE INVENTION

The present invention relates to manufacturing technology of a semiconductor device, and particularly relates to an effective technology in the application to the bump formation with a narrow pad pitch.

### 2. DESCRIPTION OF THE BACKGROUND ART

In the mounting method of a BGA package, as a mounting process in which the soldering joint of a solder bump formed in the BGA package and a land wired on a printed circuit board is performed, soldering paste is printed on the land wired on the printed circuit board through the opening of a hole made in a mask plate, by putting the mask on the printed circuit board, and applying the soldering paste on this mask. After the location of this land where the soldering paste is printed and the location of the through-hole of a structure have been put together, they are all pasted to the printed-circuit board. The BGA package is mounted after the location of the through-hole and the location of each solder bump formed in the BGA package have been matched (for example, refer to Patent Reference 1).

[Patent Reference 1] Japanese Unexamined Patent Publication 2003-46230 (FIG. 1)

### SUMMARY OF THE INVENTION

The pitch between projection electrodes (solder bump) has become very narrow as, for example 0.2 mm in accordance with the miniaturization of package size. As a formation method of a projection electrode, a screen printing method, a ball transfer method, etc. are known, for example.

In the above-mentioned screen printing method, a solder in a paste form is transferred to the electrode (wiring) of a semiconductor wafer via a mask for printing to form the projection electrodes by melting and recrystallizing (reflowing) it. In the above-mentioned ball transfer method, after a flux material is applied to a semiconductor wafer, the projection electrode is formed in a ball shape beforehand and then transferred, melted and recrystallized (reflowed) to form the projection electrodes.

Since a solder bump is formed via the mask for printing in the above-mentioned screen printing method, a ball diameter of about φ0.15 mm can be formed. However, when the pitch between the projection electrodes is very narrow, the present inventors found out that the following problems arose. The soldering paste with which an opening of the mask for printing is filled up is formed into the solder bump by melting and recrystallizing in a later reflow step (heat treating). In this respect, if reflow treatment is performed with the mask for printing being interposed, there are problems that the mask for printing is deformed by heat and that the mask for printing under heated state possibly gives damage to the semiconductor wafer to which reflow treatment is performed next, whereby it is necessary to prepare a plurality of masks for printing. For this reason, the manufacturing cost will increase. In order to prevent this problem, after a soldering paste material has been applied, then the reflow treatment is performed after the mask for printing is removed. However, if the mask for printing is removed, the soldering paste material with which the opening of the mask for printing is filled up spreads beyond the coated pad by an amount corresponding to the thickness of the mask for printing. This is because the soldering paste material has fluidity. With miniaturization of a package, when the pitch between projection electrodes is a very narrow pitch of 0.2 mm, for example, the soldering paste material which flows outward may contact with the adjacent soldering paste material. If reflowing is performed under these conditions, an electric short circuit occurs among bumps and poses a problem.

In the above-mentioned ball transfer method, since there are many balls and they are small, the difficulty of mounting poses a problem. Furthermore, in the case of the ball transfer method, since the ball diameter is for example φ0.3 mm, which is larger than that in a screen printing method because the solder bump is formed beforehand and then is transferred to the electrode of a semiconductor wafer, it is disadvantageous for the miniaturization of a package. Even if it can be formed in a smaller ball diameter, there are the following problems. In the ball transfer method, the solder bump is rolled along one in which an opening is formed corresponding to each electrode portion like the mask for printing, and the solder bump is held into each opening. However, if a solder bump's ball diameter is too small, a plurality of solder bumps will be put into the above-mentioned opening. That is, compared with a screen printing method, it is difficult to apply one solder bump correctly to one electrode.

Although the method of printing soldering paste on a land by the printing method using a squeegee is described in the above-mentioned Patent Reference 1, in this method, it is likely that short circuits between bumps will occur in the case of a narrow pad pitch.

A purpose of the present invention is to offer a manufacturing method of a semiconductor device which can form a projection electrode easily in the case of a narrow pad pitch.

Another purpose of the present invention is to offer a manufacturing method of a semiconductor device which can realize miniaturization of the semiconductor device.

The above-described and the other purposes and novel features of the present invention will become apparent from the description herein and accompanying drawings.

Of aspects of the invention disclosed in the present application, typical ones will next be summarized briefly.

That is, the present invention comprises the steps of: preparing a semiconductor wafer which has a main surface, a back surface opposite to the main surface, and an integrated circuit formed on the main surface; arranging a plurality of electrodes over the main surface of the semiconductor wafer; forming an insulating layer between the electrodes which adjoin each other without covering each of the electrodes; after the step of forming the insulating layer, applying a soldering paste material with a printing method over each of the electrodes; and forming a projection electrode by heating, melting and then recrystallizing the soldering paste material.

Further, the present invention comprises the steps of: preparing a semiconductor wafer which has a main surface, a back surface opposite to the main surface, and an integrated circuit formed on the main surface; arranging a plurality of electrodes at a first interval from each other over the main surface of the semiconductor wafer; forming a first insulating layer which covers the electrode and includes an opening exposing part of the electrode; forming a plurality of wirings each one end of which is electrically connected to one of the plurality of electrodes, over the first insulating layer so that each of the other end portions of the wirings may be arranged at a second interval from each other larger than the first interval; forming a second insulating layer which covers the wirings and includes an opening exposing each of the other end portions of the wirings; forming a third insulating layer between the other end portions which adjoin each other in the wirings; after the step of forming the third insulating layer, applying a soldering paste material with a printing method over each of the other end portions of the wirings; and forming a projection electrode by heating, melting and then hardening the soldering paste material.

Advantages achieved by some of the most typical aspects of the invention disclosed in the present application will be briefly described below.

After forming the insulating layer which does not cover each of the plurality of electrodes between the electrodes which adjoin each other, on each of the plurality of electrodes, the soldering paste material is applied with the printing method, to form a projection electrode. Thereby, the projection electrode can be formed easily, without generating the electrical short circuit between the projection electrodes (short circuit between bumps) even in the case of a narrow pad pitch.

Since formation of the projection electrode is also possible in the case of a narrow pad pitch, miniaturization of a semiconductor device can be realized.

### BRIEF DESCRIPTION OF THE DRAWINGS

FIG. 1 is a plan view showing an example of the structure of the semiconductor device of Embodiment 1 of the present invention;

FIG. 2 is an enlarged partial sectional view showing an example of the structure of the solder bump of the semiconductor device shown in FIG. 1;

FIG. 3 is a plan view showing an example of the structure of the semiconductor wafer used for the assembly of the semiconductor device shown in FIG. 1;

FIG. 4 is a manufacture process flow chart showing an example of the assembly procedure up to the insulating layer formation in manufacture of the semiconductor device shown in FIG. 1;

FIG. 5 is a manufacture process flow chart showing an example of the assembly procedure of the soldering paste material application in manufacture of the semiconductor device shown in FIG. 1;

FIG. 6 is a plan view showing an example of the structure of the semiconductor wafer after the solder bump formation in manufacture of the semiconductor device shown in FIG. 1;

FIG. 7 is an enlarged partial plan view showing the structure of the section A shown in FIG. 6;

FIG. 8 is a plan view showing the structure of the semiconductor device of a modification of Embodiment 1 of the present invention;

FIG. 9 is an enlarged partial sectional view showing an example of the structure of the solder bump of the semiconductor device shown in FIG. 8;

FIG. 10 is a manufacture process flow chart showing the assembly procedure up to the insulating layer formation in manufacture of the semiconductor device of the modification shown in FIG. 8;

FIG. 11 is a manufacture process flow chart showing the assembly procedure of the soldering paste material application in manufacture of the semiconductor device of the modification shown in FIG. 8;

FIG. 12 is an enlarged partial plan view showing a part of structures of the semiconductor wafer after the solder bump formation in manufacture of the semiconductor device of the modification shown in FIG. 8;

FIG. 13 is a manufacture process flow chart showing an example of the assembly procedure up to the insulating layer formation in manufacture of the semiconductor device of Embodiment 2 of the present invention;

FIG. 14 is a manufacture process flow chart showing an example of the assembly procedure of the soldering paste material application in manufacture of the semiconductor device of Embodiment 2 of the present invention;

FIG. 15 is a manufacture process flow chart showing an example of the assembly procedure up to the insulating layer formation in manufacture of the semiconductor device of Embodiment 3 of the present invention; and

FIG. 16 is a manufacture process flow chart showing an example of the assembly procedure of the soldering paste material application in manufacture of the semiconductor device of Embodiment 3 of the present invention.

### DETAILED DESCRIPTION OF THE PREFERRED EMBODIMENTS

In the following embodiments, except the time when especially required, explanation of identical or similar part is not repeated in principle.

In the below-described embodiments, a description will be made after divided into plural sections or in plural embodiments if necessary for convenience sake. These plural sections or embodiments are not independent each other, but in relation such that one is a modification example, details or complementary description of a part or whole of the other one unless otherwise specifically indicated.

In the below-described embodiments, when a reference is made to the number of elements (including the number, value, amount and range), the number is not limited to a specific number but may be equal to or greater than or less than the specific number, unless otherwise specifically indicated or principally apparent that the number is limited to the specific number.

Hereafter, embodiments of the invention are explained in detail based on drawings. In all the drawings for describing the embodiments, members of a like function will be identified by like reference numerals and overlapping descriptions will be omitted.

### Embodiment 1

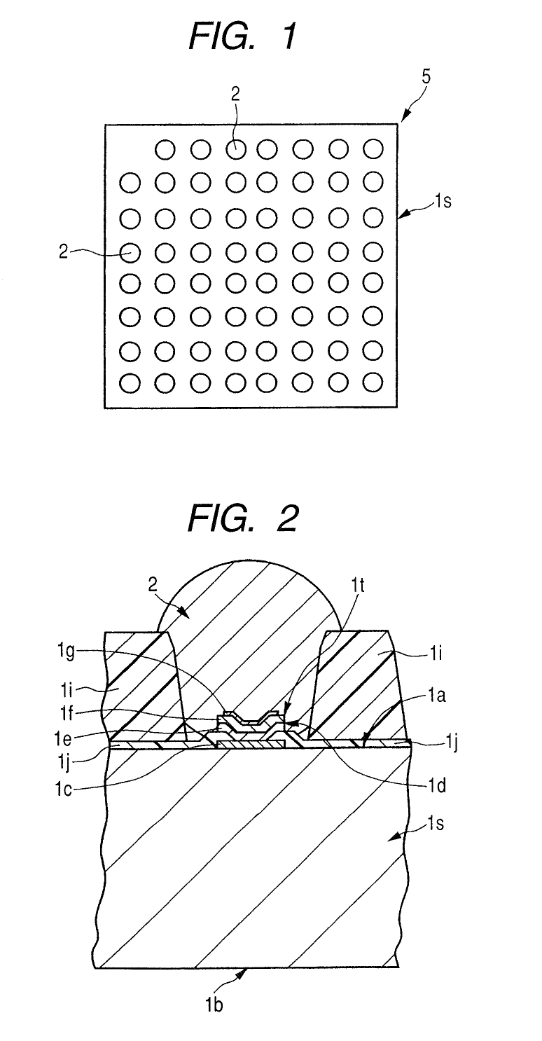

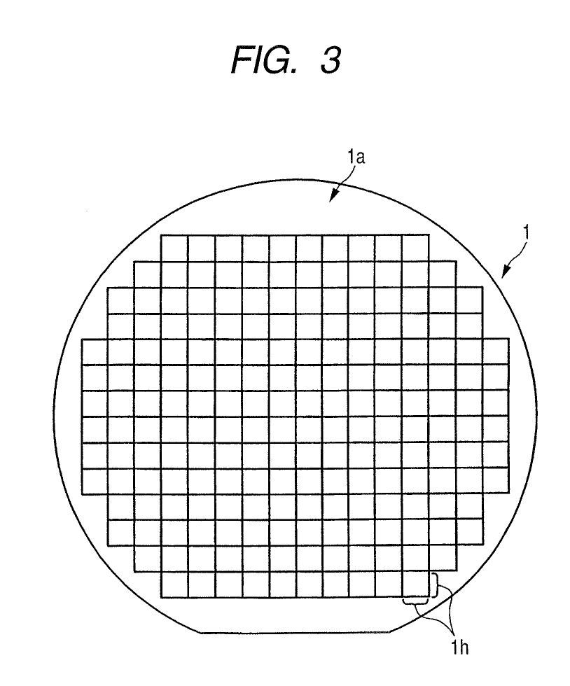

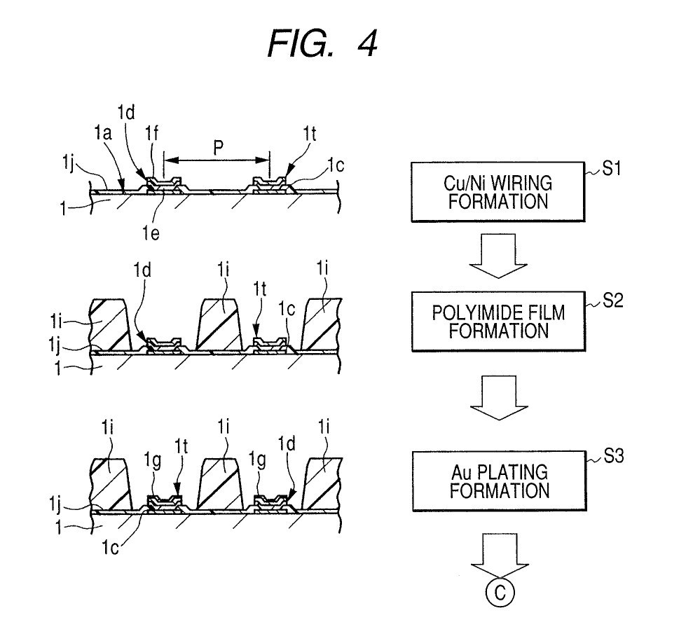

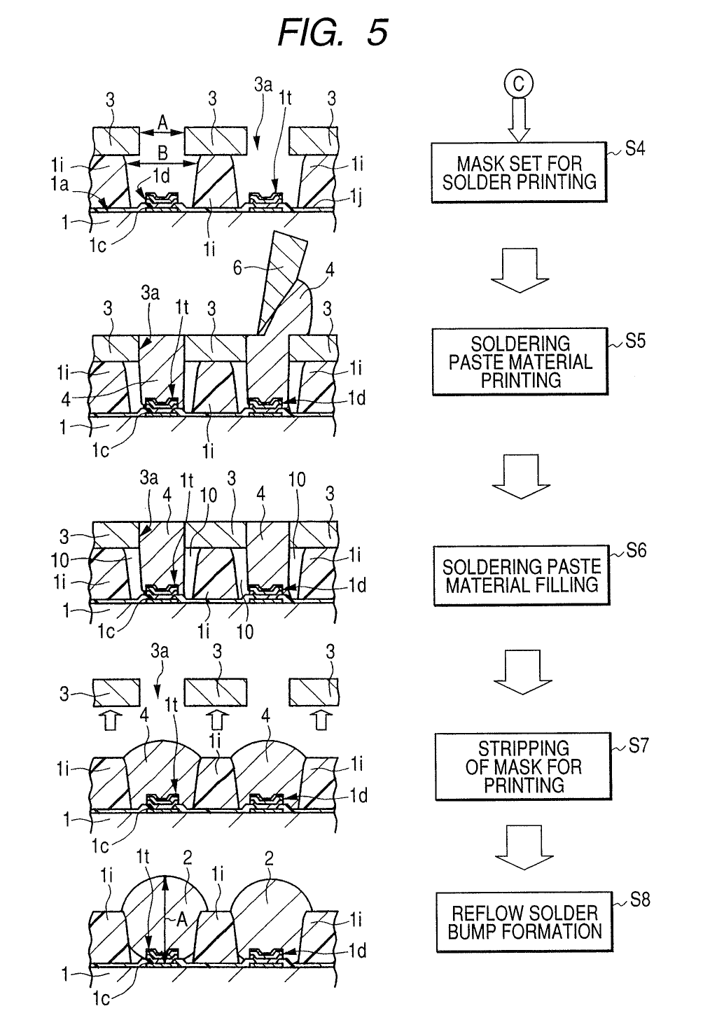

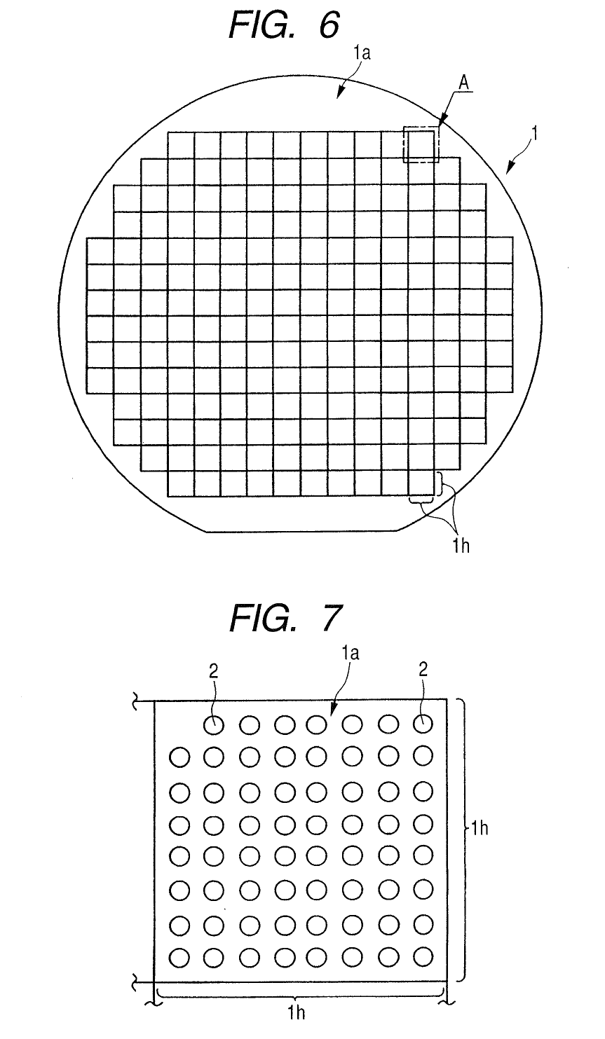

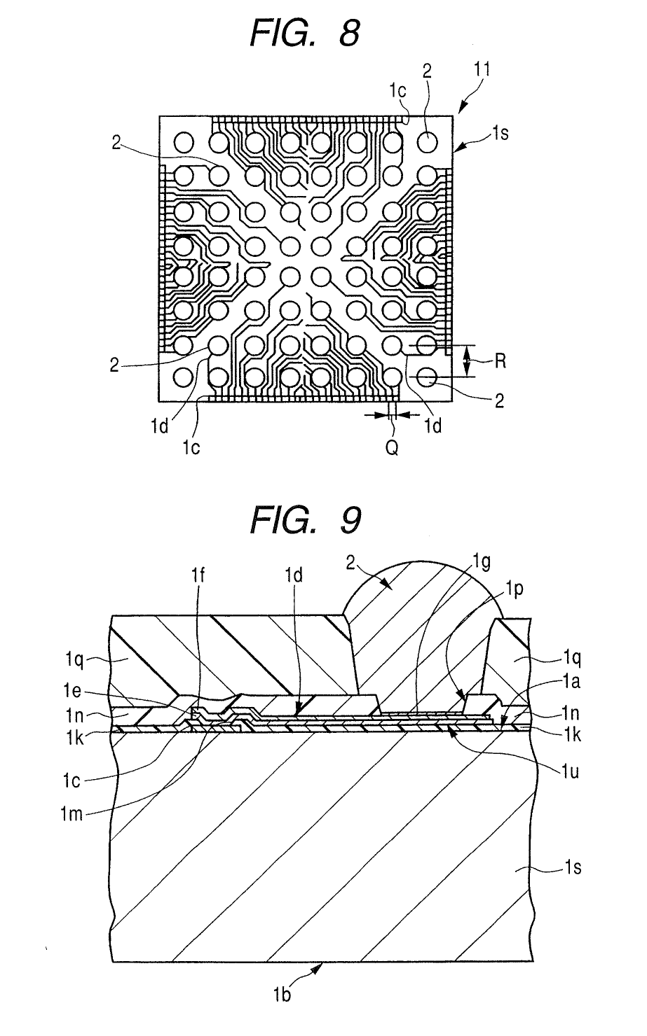

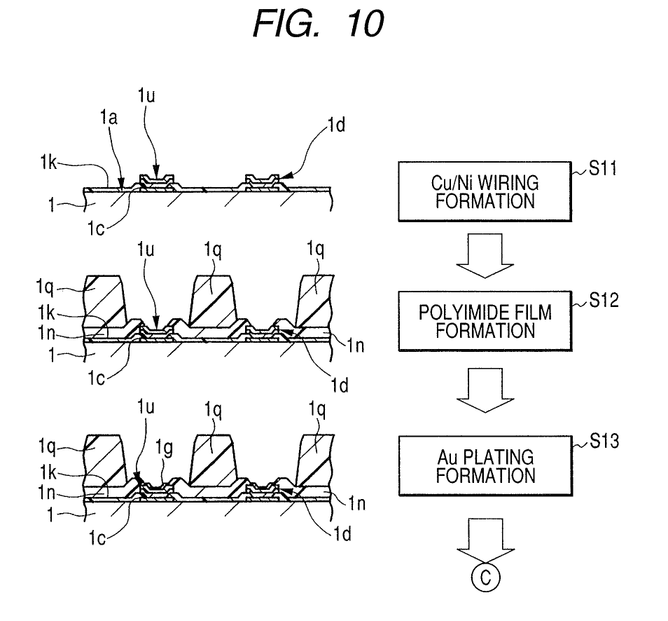

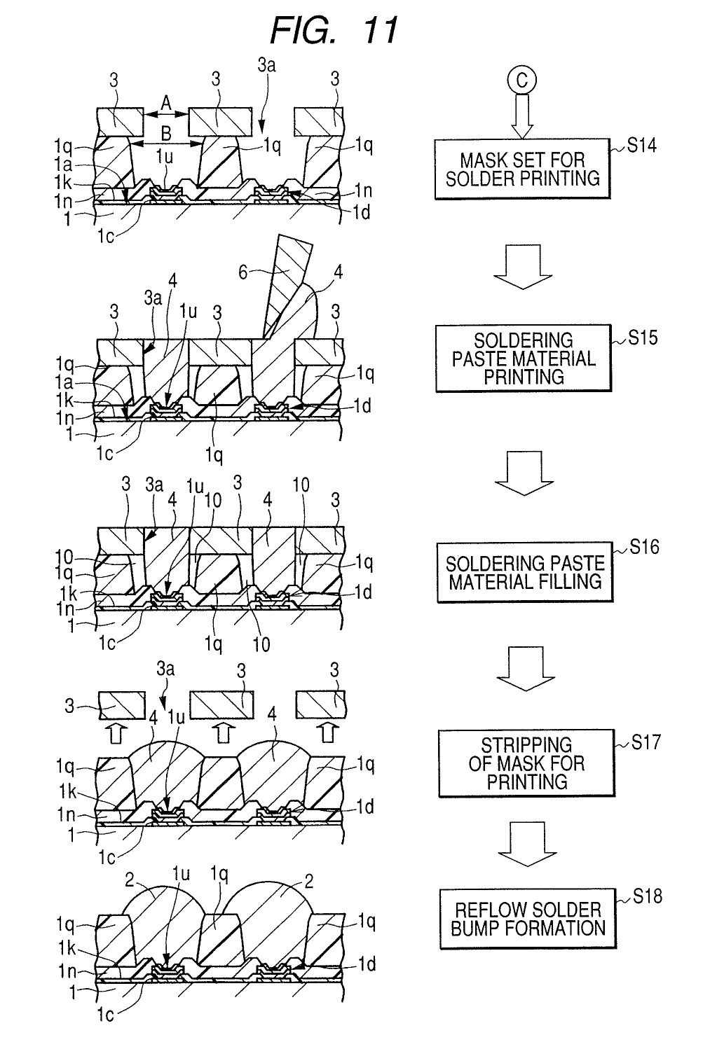

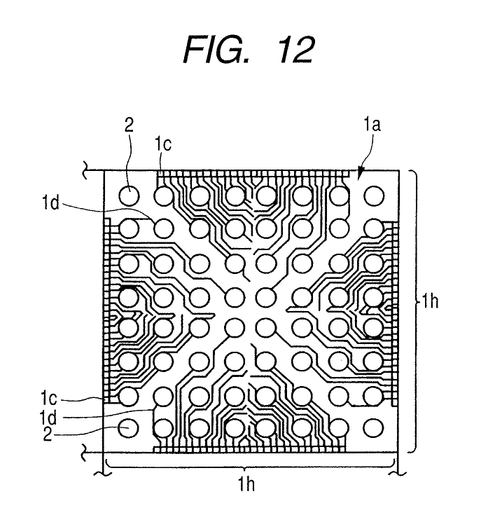

FIG. 1 is a plan view showing an example of the structure of the semiconductor device of Embodiment 1 of the present invention, FIG. 2 is an enlarged partial sectional view showing an example of the structure of the solder bump of the semiconductor device shown in FIG. 1, FIG. 3 is a plan view showing an example of the structure of the semiconductor wafer used for the assembly of the semiconductor device shown in FIG. 1, FIG. 4 is a manufacture process flow chart showing an example of the assembly procedure up to the insulating layer formation in manufacture of the semiconductor device shown in FIG. 1, FIG. 5 is a manufacture process flow chart showing an example of the assembly procedure of the soldering paste material application in manufacture of the semiconductor device shown in FIG. 1, FIG. 6 is a plan view showing an example of the structure of the semiconductor wafer after the solder bump formation in manufacture of the semiconductor device shown in FIG. 1, FIG. 7 is an enlarged partial plan view showing the structure of the section A shown in FIG. 6, FIG. 8 is a plan view showing the structure of the semiconductor device of a modification of Embodiment 1 of the present invention, FIG. 9 is an enlarged partial sectional view showing an example of the structure of the solder bump of the semiconductor device shown in FIG. 8, FIG. 10 is a manufacture process flow chart showing the assembly procedure up to the insulating layer formation in manufacture of the semiconductor device of the modification shown in FIG. 8, FIG. 11 is a manufacture process flow chart showing the assembly procedure of the soldering paste material application in manufacture of the semiconductor device of the modification shown in FIG. 8, and FIG. 12 is an enlarged partial plan view showing a part of structures of the semiconductor wafer after the solder bump formation in manufacture of the semiconductor device of the modification shown in FIG. 8.

As for semiconductor device 5 of Embodiment 1 shown in FIG. 1, solder bump 2 which is a projection electrode is connected to each of pads 1c which are a plurality of surface electrodes formed on main surface 1a of semiconductor chip 1s as shown in FIG. 2, and a plurality of solder bumps 2 are arranged in a grid configuration at a predetermined spacing, as shown in FIG. 1.

In semiconductor device 5 of Embodiment 1, polyimide film 1i which is an insulating layer is formed among a plurality of solder bumps 2 which adjoin one another on main surface 1a of semiconductor chips 1s.

In semiconductor device 5, the formation pitch of pads 1c is a narrow pitch of 0.2 mm or less, for example, and semiconductor device 5 is mainly included in a semiconductor package etc.

Next, the manufacturing method of the semiconductor device of Embodiment 1 is explained.

First, semiconductor wafer 1 as shown in the FIG. 3 which has main surface 1a, back surface 1b opposite to main surface 1a, and an integrated circuit formed on main surface 1a is prepared. In main surface 1a of semiconductor wafer 1, block formation of a plurality of element formation regions 1h is performed, and pads 1c which are a plurality of surface electrodes and the above-mentioned integrated circuit are formed in each element formation region 1h. Pad 1c includes, for example an aluminum alloy, and as shown in FIG. 2, the central part except the peripheral part is exposed from protective film 1j. That is, while thin protective film 1j is formed on main surface 1a of semiconductor wafer 1, this protective film 1j covers only the peripheral part of pad 1c and does not cover the central part of pad 1c.

As for pads 1c of Embodiment 1, as shown in FIG. 4, the pitch between adjoining pads, i.e., the pitch (P) between the pads, is a narrow pad pitch of P=0.2 mm or less, for example.

Then, Cu/Ni wiring formation shown in step S1 of FIG. 4 is performed. Here, Cu/Ni wiring 1d is formed by connecting to each pad 1c so that land (electrode) 1t which includes Cu/Ni wiring 1d is formed on each pad 1c. Land 1t includes Cu layer 1e and Ni layer 1f.

Polyimide film formation shown in step S2 is performed after land formation. Here, a insulating layer which does not cover any of a plurality of pads 1c is formed between pads 1c which adjoin each other. The insulating layer in this Embodiment is polyimide film 1i which includes polyimide resin, for example. In the case of forming the above-mentioned polyimide film 1i, polyimide film 1i is formed with a printing method between adjoining pads 1c (between lands 1t), for example.

As shown in step S2 of FIG. 4, polyimide film 1i is formed between lands 1t so that the height (thickness) of polyimide film 1i may become sufficiently higher than that of land 1t. In other words, it is formed so that the top face of polyimide film 1i may lie higher than (above) the top face of land 1t. If it is formed too high, polyimide film 1i may become long and slender-shaped because it is formed between narrow pitches, and the above-mentioned polyimide film 1i may fall. Therefore, as for the height of polyimide film 1i, it is preferred that it is about ½ of the pitch between pads (P) or less.

Then, as shown in step S3 of FIG. 4, Au plating formation is performed. Here, Au plating 1g is formed on the surface of each land 1t so that the reaction of land 1t and solder is made good.

Soldering paste material 4 shown in FIG. 5 is applied with the printing method on each of a plurality of lands 1t after Au plating formation. First, mask for printing 3 shown in step S4 of FIG. 5 is prepared.

Mask for printing 3 of Embodiment 1 has a plurality of openings 3a whose opening distance (A) is made smaller than the distance (B) between the end portions of adjoining polyimide film 1i, as shown in step S4 of FIG. 5. That is, mask for printing 3 having the relation of the distance (B) between the end portions of adjoining polyimide film 1i>the opening distance (A) of mask for printing 3 is used.

As shown in step S4 of FIG. 5, mask for printing 3 is arranged on polyimide film 1i so that opening 3a of mask for printing 3 may be arranged between adjoining polyimide films 1i.

Then, soldering paste material printing shown in step S5 is performed. Soldering paste material 4 comprises solder and flux, for example. Here, soldering paste material 4 is applied on land 1t between polyimide films 1i by squeegee 6 through opening 3a of mask for printing 3. Soldering paste material filling shown in step S6 is performed by continuing the above-mentioned application. That is, soldering paste material 4 is filled up on land 1t between polyimide films 1i.

Although mask for printing 3 which has the relation: the distance (B) between the end portions of adjoining polyimide films 1i>the opening distance (A) of mask for printing 3 is used, since surface tension works at opening 3a of mask for printing 3 and it is held in a state that soldering paste material 4 stands, clearance 10 is formed between soldering paste material 4 and polyimide film 1i.

Then, stripping of mask for printing shown in step S7 of FIG. 5 is performed. Here, mask for printing 3 is made to secede from polyimide film 1i, and hereby soldering paste material 4 fills up without any clearance between polyimide films 1i. That is, when mask for printing 3 is stripped, the surface tension in opening 3a will be released, and liquid soldering paste material 4 flows into clearance 10. Therefore, since soldering paste material 4 of the amount corresponding to the thickness of mask for printing 3 flows into clearance 10, and polyimide film 1i arranged between lands 1t serves as a dam, adjoining soldering paste material 4 can be prevented from coming into contact with each other.

Then, reflow solder bump formation shown in step S8 of FIG. 5 is performed. Here, by reflow treatment, heat melting of the soldering paste material 4 is performed, and then solder bump 2 is formed on each land 1t by recrystallization. That is, by heat melting and recrystallization of soldering paste material 4, solder bump 2 is formed.

Changes are not observed in the shape of solder bump 2 before and after reflow treatment. However, since solder bump 2 changes with reflow treatment toward a solid sphere shape which has low stress, as shown in step S8 of FIG. 5, diameter (height) A becomes a little larger than that before the reflow treatment.

When the reflow treatment is performed without removing mask for printing 3, the flux of soldering paste material 4 adheres to mask for printing 3, and mask cleaning is needed. Where mask for printing 3 is heated, since printing of the following semiconductor wafer 1 cannot be performed and the shape of mask for printing 3 changes with heat in some cases, whenever one wafer is printed, mask for printing 3 must be exchanged. This affects its suitability for mass production negatively and also increases the manufacturing cost.

Therefore, in the manufacturing method of the semiconductor device of Embodiment 1, after removing mask for printing 3, reflow treatment to soldering paste material 4 is performed.

After solder bump formation, as shown in the enlarged view of FIG. 7, a plurality of solder bumps 2 arranged in a grid configuration are formed in each element formation region 1h on main surface 1a of semiconductor wafer 1 shown in FIG. 6.

Then, the assembly of semiconductor device 5 shown in FIG. 1 is completed by individual separation by performing dicing along a dicing line.

According to the manufacturing method of the semiconductor device of Embodiment 1, in a plurality of lands 1t, the polyimide film 1i which does not cover each of the plurality of lands 1t is formed between respective adjoining lands 1t. Then, on each of the plurality of lands 1t, soldering paste material 4 is applied with the printing method, and solder bump 2 is formed. Thereby, since polyimide film 1i formed between adjoining lands 1t serves as a dam, solder bump 2 can be formed without generating an electrical short circuit between solder bumps 2 (short circuit between bumps) even in the case of a narrow pad pitch.

That is, since polyimide film 1i serves as a dam and the effective distance between bumps becomes long, the electric short circuit between the bumps can be prevented. For example, in the case of a narrow pad pitch that a pad pitch is 0.2 mm or less, realization of solder bump formation with the printing method can be planned.

Since solder bump 2 can be formed corresponding to a narrow pad pitch, miniaturization of semiconductor chips 1s can be realized, and, as a result, miniaturization of semiconductor device 5 which has semiconductor chips 1s can be realized.

Since solder bump 2 corresponding to a narrow pad pitch can be formed with the printing method, the manufacturing cost in an assembly can be held down compared with a ball transfer method, and the formation of solder bump 2 in the case of a narrow pad pitch can be realized at low cost.

Since solder bump 2 of a smaller diameter than that by the ball transfer method can be formed by forming a solder bump with the printing method, miniaturization of semiconductor device 5 can be realized.

Next, a modification of Embodiment 1 is explained.

In semiconductor device 11 of the modification shown in FIG. 8, about arrangement of pad 1c in semiconductor chips 1s, as shown in FIG. 9, the pitch is expanded and rearrangement is performed with rewiring of Cu/Ni wiring 1d. The pitch between solder bumps 2 is larger than the pitch between pads 1c. That is, solder bump 2 is made easy to mount by making the land pitch larger than the pad pitch with re-wiring, in order to make it correspond to a narrow pad pitch.

Also in semiconductor device 11, a plurality of solder bumps 2 are arranged in a grid configuration with a predetermined spacing, as shown in FIG. 8. Also in semiconductor device 11, polyimide film 1q of a third insulating layer is formed among a plurality of solder bumps 2 which adjoin one another as shown in FIG. 9.

In semiconductor device 11 as well, the formation pitch of pad 1c is a narrow pitch of 0.2 mm or less like semiconductor device 5, for example. Although the land pitch of bump land 1u in which solder bump 2 is formed is enlarged by the rearrangement, the pitch between solder bumps 2 in semiconductor device 11 is also a narrow pitch of 0.2 mm or less.

Next, a modification of the manufacturing method of semiconductor device 11 is explained.

First, semiconductor wafer 1 which has main surface 1a, back surface 1b opposite to main surface 1a, and an integrated circuit formed on main surface 1a as shown in FIG. 3 is prepared. In main surface 1a of semiconductor wafer 1, block formation of a plurality of element formation regions 1h is performed, and pads 1c which are a plurality of surface electrodes, and the above-mentioned integrated circuit are formed in each element formation region 1h. Pad 1c includes, for example an aluminum alloy, and pads 1c adjoining each other are arranged at a first spacing (Q) as shown in FIG. 8. For example, the pitch between pads 1c (Q) is arranged with a narrow pad pitch of Q=0.2 mm or less.

Then, on main surface 1a of semiconductor wafer 1, as shown in FIG. 9, first insulating layer 1k which covers each pad 1c and includes openings 1m exposing the central part (part) of pad 1c is formed. Thereby, as for each pad 1c, the central part except the peripheral part is exposed. That is, although thin first insulating layer 1k was formed on main surface 1a of semiconductor wafer 1, this first insulating layer 1k covers only the peripheral part of pad 1c but does not cover the central part of pad 1c.

Then, Cu/Ni wiring formation shown in step S11 of FIG. 10 is performed. Here, as shown in FIG. 9, it forms so that one end of each of a plurality of Cu/Ni wirings 1d may connect with pad 1c electrically. Cu/Ni wirings 1d which are a plurality of re-wirings are formed on first insulating layer 1k so that bump lands 1u each of which is an end portion of the plurality of Cu/Ni wirings 1d may be arranged at a second spacing (R) larger than the first spacing (Q) as shown in FIG. 8. For example, the pitch between solder bumps 2 (R) is arranged with the narrow pitch of R=0.2 mm or less as well as the pitch between pads 1c. Cu/Ni wiring 1d includes Cu layer 1e and Ni layer 1f.

Then, as shown in FIG. 9, polyimide films (second insulating layer) 1n which cover a plurality of Cu/Ni wirings 1d, and include opening 1p exposing each bump land 1u in the plurality of Cu/Ni wirings 1d, are formed.

Then, polyimide film formation shown in step S12 of FIG. 10 is performed. Here, polyimide film 1q which is a third insulating layer is formed between bump lands 1u which adjoin one another in a plurality of Cu/Ni wirings 1d. In that case, polyimide film 1q is formed between adjoining bump lands 1u using polyimide resin with, for example, the printing method.

As shown in FIG. 9, polyimide film 1q is formed so that the height (thickness) may become sufficiently higher than the height (thickness) of bump land 1u of Cu/Ni wiring 1d. In other words, it is formed so that the top face of third insulating layer 1q may lie at a level higher than (above) the top face of bump land 1u, and also higher than the top face of second insulating layers 1n. Like semiconductor device 5, if formed too high, polyimide film 1q may become long and slender-shaped since it is formed between narrow pitches, and the above-mentioned polyimide film 1q may fall. Therefore, it is preferred that the height of polyimide film 1q is about ½ of the pitch between pads (P) or less.

Then, as shown in step S13 of FIG. 10, Au plating formation is performed. Here, Au plating 1g is formed on the surface of each bump land 1u in Cu/Ni wiring 1d so that the reaction of bump land 1u and solder is made good.

After Au plating formation, soldering paste material 4 shown in FIG. 11 is applied with the printing method on each bump land 1u in a plurality of Cu/Ni wirings 1d. First, mask for printing 3 shown in step S14 of FIG. 11 is prepared.

Mask for printing 3 has a plurality of openings 3a whose opening distance (A) is formed smaller than the distance (B) between the end portions of adjoining polyimide film 1q as shown in FIG. 5. That is, mask for printing 3 having the relation: the distance (B) between the end portions of adjoining polyimide film 1q>the opening distance (A) of mask for printing 3 is used.

As shown in step S14 of FIG. 11, mask for printing 3 is arranged on polyimide film 1q so that opening 3a of mask for printing 3 may be arranged between adjoining polyimide films 1q.

Then, soldering paste material printing shown in step S15 is performed. Here, soldering paste material 4 is applied by squeegee 6 through opening 3a of mask for printing 3 on bump land 1u of Cu/Ni wiring 1d between polyimide films 1q. Soldering paste material filling shown in step S16 is performed by continuing the above-mentioned application. That is, soldering paste material 4 is filled up on bump land 1u between polyimide films 1q.

Although mask for printing 3 having the relation: distance (B) between the end portions of adjoining polyimide film 1q>the opening distance (A) of mask for printing 3 is used, since surface tension works in opening 3a of mask for printing 3 and it is held in a state that soldering paste material 4 stands, clearance 10 is formed between soldering paste material 4 and polyimide film 1q.

Then, stripping of mask for printing shown in step S17 is performed. Here, mask for printing 3 is made to secede from polyimide film 1q, and soldering paste material 4 is filled up with no clearance between polyimide films 1q. That is, when mask for printing 3 is stripped, the surface tension of opening 3a is released, and liquid soldering paste material 4 flows into clearance 10. Therefore, since soldering paste material 4 of the amount corresponding to the thickness of mask for printing 3 flows into clearance 10 and polyimide film 1q arranged between bump lands 1u serves as a dam, adjoining soldering paste material 4 can be prevented from coming into contact with each other.

Then, reflow solder bump formation shown in step S18 of FIG. 11 is performed. Here, by reflow treatment, heat melting of the soldering paste material 4 is performed, and then solder bump 2 is formed on each bump land 1u of Cu/Ni wiring 1d by recrystallization. That is, solder bump 2 is formed by performing melting and recrystallization of soldering paste material 4.

After solder bump formation, as shown in the enlarged view of FIG. 12, a plurality of solder bumps 2 arranged in a grid configuration are formed in each element formation region 1h on main surface 1a of semiconductor wafer 1 shown in FIG. 6.

Then, the assembly of semiconductor device 11 of the modification shown in FIG. 8 is completed by individual separation by performing dicing along a dicing line.

Also in the manufacturing method of semiconductor device 11 of the modification of Embodiment 1, by forming polyimide film 1q between respective adjoining bump lands 1u in a plurality of Cu/Ni wirings 1d which are re-wirings, and after that forming a solder bump 2 on each of a plurality of bump lands 1u applying soldering paste material 4 with the printing method, solder bump 2 can be formed without generating an electric short circuit between solder bumps 2 (short circuit between bumps) even in the case of a narrow pad pitch. For example, in the narrow pad pitch that a pad pitch and a land pitch are 0.2 mm or less, realization of solder bump formation with the printing method can be realized.

Regarding other effects which are obtained by the manufacturing method of semiconductor device 11 of a modification, since it is the same as what is explained about the effect which is obtained by the manufacturing method of semiconductor device 5, duplicate explanation is omitted.

### Embodiment 2

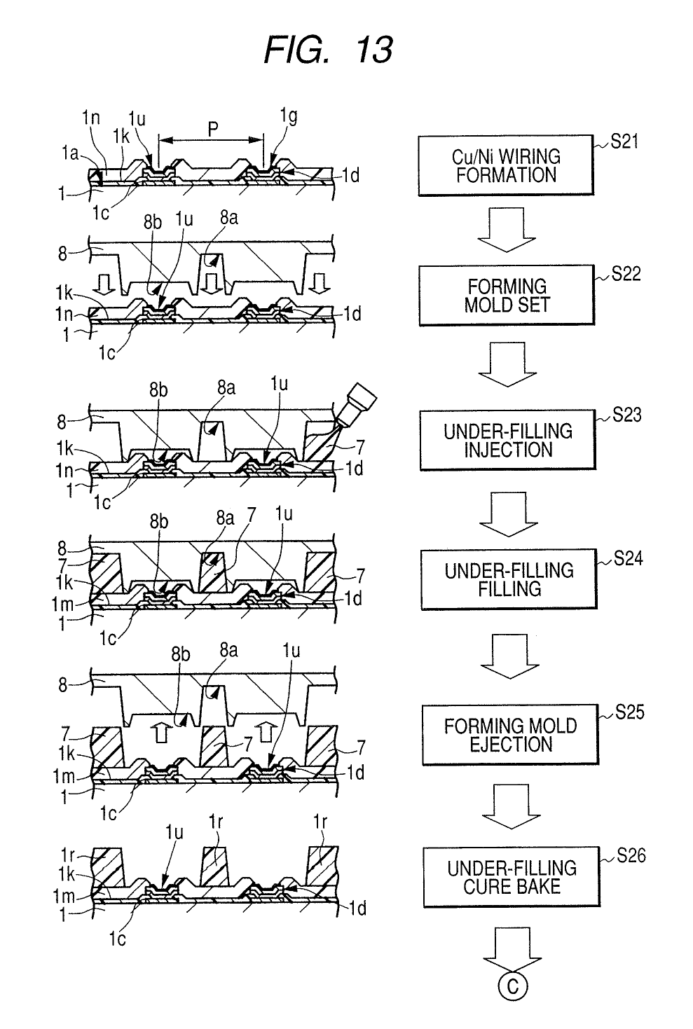

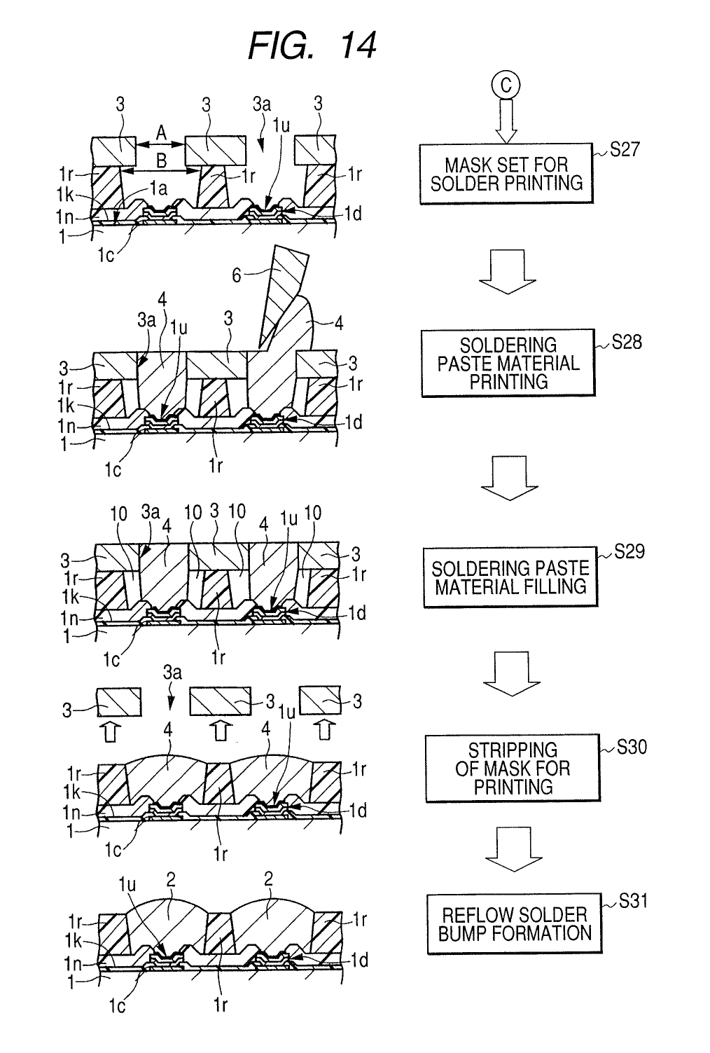

FIG. 13 is a manufacture process flow chart showing an example of the assembly procedure up to the insulating layer formation in manufacture of the semiconductor device of Embodiment 2 of the present invention, and FIG. 14 is a manufacture process flow chart showing an example of the assembly procedure of the soldering paste material application in manufacture of the semiconductor device of Embodiment 2 of the present invention.

The manufacturing method of the semiconductor device of Embodiment 2 explains the formation method of the insulating layer arranged between adjoining bump lands 1u connected to pad 1c, and the application of soldering paste material 4 on main surface 1a of semiconductor wafer 1 as an example of a bump formation method.

First, semiconductor wafer 1 as shown in the FIG. 3 which has main surface 1a, back surface 1b which is opposite to main surface 1a, and an integrated circuit formed on main surface 1a is prepared. Then, first insulating layer 1k which covers the peripheral part of pad 1c is formed on main surface 1a of semiconductor wafer 1 as in the modification of Embodiment 1.

Then, Cu/Ni wiring formation shown in step S21 of FIG. 13 is performed. Here, Cu/Ni wiring 1d is formed by connecting with pad 1c electrically. Polyimide film 1n which is a second insulating layer is formed on first insulating layer 1k so that bump land 1u of Cu/Ni wiring 1d is exposed. The pitch (P) of pad 1c is arranged by a narrow pad pitch of P=0.2 mm or less, for example.

Then, the forming mold set shown in step S22 is performed. First, forming mold 8 which is a guide post is arranged so that a mold cavity 8a of forming mold 8 is arranged facing the space between adjoining bump lands 1u of Cu/Ni wiring 1d. That is, forming mold 8 is arranged so that mold cavity 8a of forming mold 8 corresponds to the space between bump lands 1u and roll off 8b which is formed to adjoin mold cavity 8a may correspond to a position over bump land 1u. In that case, each of the opening sides of mold cavity 8a and roll off 8b is arranged facing main surface 1a of semiconductor wafer 1.

Then, under-filling injection shown in step S23 is performed. That is, by injecting under-filling 7 which is insulating resin into mold cavity 8a of forming mold 8, and further performing under-filling filling shown in step S24, under-filling 7 is filled up in each mold cavity 8a.

Under-filling 7 is thermosetting resin, for example.

Then, forming mold ejection shown in step S25 of FIG. 13 is performed. That is, forming mold 8 which is a guide post is made to secede from semiconductor wafer 1. Here, forming mold 8 is made to secede from semiconductor wafer 1 by raising forming mold 8.

Then, heat curing of the under-filling 7 is carried out by performing under-filling cure bake shown in step S26. Thereby, insulating layer 1r including insulating resin can be formed between the electrodes on main surface 1a of semiconductor wafer 1 (i.e., between bump lands 1u).

Then, soldering paste material 4 shown in FIG. 14 is applied with the printing method on each bump land 1u like Embodiment 1. First, mask for printing 3 shown in step S27 of FIG. 14 is prepared.

Mask for printing 3 has a plurality of openings 3a whose opening distance (A) is formed smaller than the distance (B) between the end portions of adjoining insulating layer 1r as shown in FIG. 5. That is, mask for printing 3 having the relation: the distance (B) between the end portions of adjoining insulating layer 1r>the opening distance (A) of mask for printing 3 is used.

As shown in step S27 of FIG. 14, mask for printing 3 is arranged on insulating layer 1r so that opening 3a of mask for printing 3 may be arranged between adjoining insulating layers 1r.

Then, soldering paste material printing shown in step S28 is performed. Here, soldering paste material 4 is applied on bump land 1u between insulating layers 1r by squeegee 6 through opening 3a of mask for printing 3. Soldering paste material filling shown in step S29 is performed by continuing the above-mentioned application. That is, soldering paste material 4 is filled up on bump land 1u between insulating layers 1r.

Although mask for printing 3 having the relation: the distance (B) between the end portions of adjoining polyimide film 1r>the opening distance (A) of mask for printing 3 is used, since surface tension works in opening 3a of mask for printing 3 and it is held in the state that soldering paste material 4 stands, clearance 10 is formed between soldering paste material 4 and insulating layer 1r.

Then, stripping of mask for printing shown in step S30 is performed. Here, mask for printing 3 is made to secede from insulating layer 1r, and soldering paste material 4 fills up without any clearance between insulating layers 1r. That is, when the mask for printing 3 is stripped, the surface tension of opening 3a will be released, and liquid soldering paste material 4 flows into clearance 10. Therefore, since soldering paste material 4 of the amount corresponding to the thickness of mask for printing 3 flows into clearance 10 and insulating layer 1r arranged between bump lands 1u serves as a dam, adjoining soldering paste material 4 can be prevented from coming into contact with each other.

Then, reflow solder bump formation shown in step S31 of FIG. 14 is performed. Here, by reflow treatment, heat melting of soldering paste material 4 is performed, and then solder bump 2 is formed on each bump land 1u of Cu/Ni wiring 1d by hardening. That is, solder bump 2 is formed by performing heat curing of soldering paste material 4.

Also in the manufacturing method of the semiconductor device of Embodiment 2, by forming insulating layer 1r between respective adjoining bump lands 1u in a plurality of Cu/Ni wirings 1d which are re-wirings, and then forming solder bump 2 by applying soldering paste material 4 with the printing method on each of a plurality of bump lands 1u, solder bump 2 can be formed without generating the electric short circuit between solder bumps 2 (short circuit between bumps) even in the case of a narrow pad pitch.

Regarding other effects which are obtained by the manufacturing method of semiconductor device of Embodiment 2, since it is the same as what is explained about the effect which is obtained by the manufacturing method of semiconductor device 5 of Embodiment 1, duplicate explanation is omitted.

### Embodiment 3

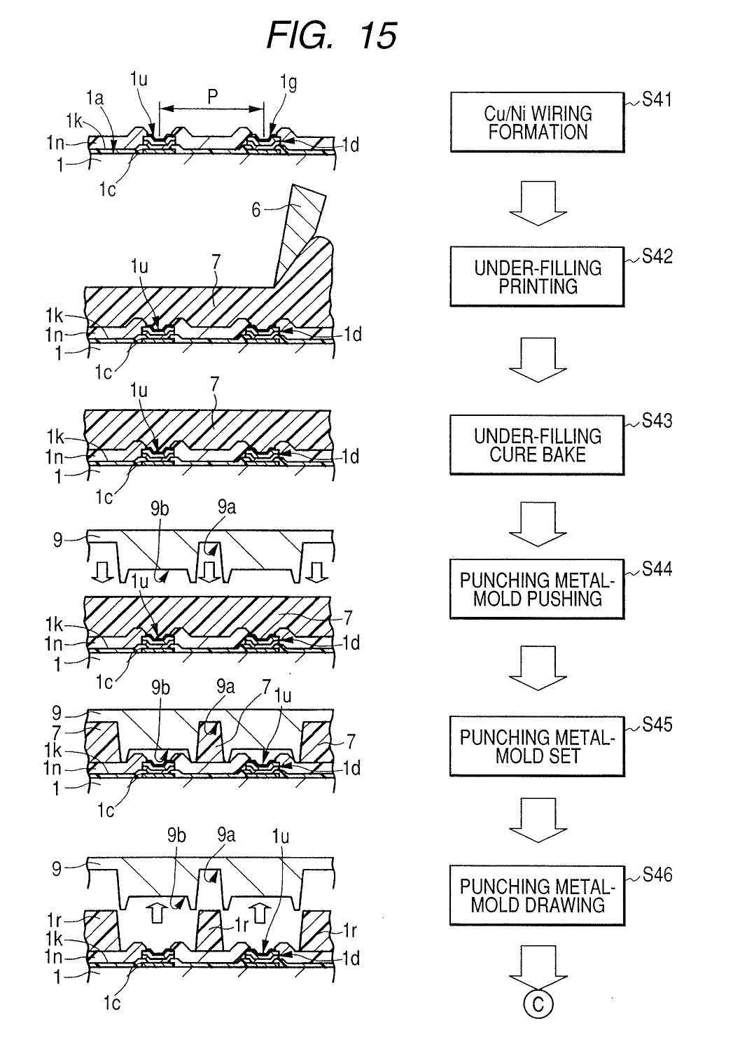

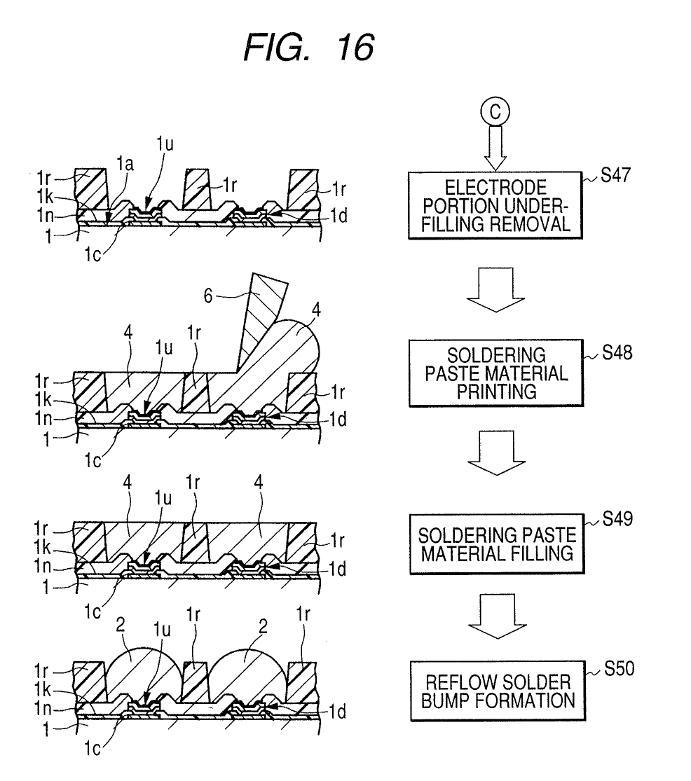

FIG. 15 is a manufacture process flow chart showing an example of the assembly procedure up to the insulating layer formation in manufacture of the semiconductor device of Embodiment 3 of the present invention, and FIG. 16 is a manufacture process flow chart showing an example of the assembly procedure of the soldering paste material application in manufacture of the semiconductor device of Embodiment 3 of the present invention.

The manufacturing method of the semiconductor device of Embodiment 3 explains the formation method of the insulating layer arranged between adjoining bump lands 1u connected to pad 1c, and the application of soldering paste material 4 on main surface 1a of semiconductor wafer 1 as an example of a bump formation method.

First, semiconductor wafer 1 as shown in FIG. 3 which has main surface 1a, back surface 1b opposite to main surface 1a, and an integrated circuit formed on the main surface 1a is prepared. Then, first insulating layer 1k which covers the peripheral part of pad 1c is formed on main surface 1a of semiconductor wafer 1 as in the modification of Embodiment 1.

Then, Cu/Ni wiring formation shown in step S41 of FIG. 15 is performed. Here, Cu/Ni wiring 1d is formed by connecting with pad 1c electrically. Polyimide films 1n which is a second insulating layer are formed on first insulating layer 1k so that bump land 1u of Cu/Ni wiring 1d is exposed. The pitch (P) of pad 1c is arranged with a narrow pad pitch of P=0.2 mm or less, for example.

Then, under-filling printing shown in step S42 of FIG. 15 is performed. Here, on main surface 1a of semiconductor wafer 1, under-filling 7 being insulating resin is applied using squeegee 6. Under-filling 7 is thermosetting resin, for example.

Then, heat curing of the under-filling 7 is carried out by performing under-filling cure bake shown in step S43.

Then, punching metal-mold pushing shown in step S44 is performed. Here, punching metal mold 9 which is a comb type metal mold having depressed portion 9a and roll off 9b adjoining this is prepared, and punching metal mold 9 is arranged so that the opening side of depressed portion 9a and roll off 9b may oppose to under-filling 7.

Then, punching metal-mold setting shown in step S45 is performed. Here, after punching metal mold 9 is arranged on under-filling 7 so that depressed portion 9a of punching metal mold 9 faces the space between adjoining bump lands 1u, and so that roll off 9b faces the bump land 1u, punching metal mold 9 is driven into under-filling 7 so that under-filling 7 fills up depressed portion 9a of punching metal mold 9. Thereby, under-filling 7 is filled up in depressed portion 9a.

Then, punching metal-mold drawing shown in step S46 is performed. That is, punching metal mold 9 is made to secede from semiconductor wafer 1. Punching metal mold 9 is made to secede from semiconductor wafer 1 by raising punching metal mold 9 here. Thereby, insulating layer 1r including insulating resin can be arranged between the electrodes on main surface 1a of semiconductor wafer 1 (i.e., between bump lands 1u).

Then, electrode portion under-filling removal shown in step S47 of FIG. 16 is performed. Here, under-filling 7 which adheres on the electrode, i.e., bump land 1u, is removed with an ashing method etc., for example.

Then, soldering paste material printing shown in step S48 is performed. Here, soldering paste material 4 is directly applied on bump land 1u between insulating layers 1r by squeegee 6. In Embodiment 3, since under-filling 7 including thermosetting resin as insulating layer 1r is used, formed insulating layer 1r has hardness higher than the polyimide resin used in Embodiment 1. Therefore, even if mask for printing 3 is not used, it is possible to use this insulating layer 1r itself as a mask substitute. Hereby, it is possible to reduce a manufacturing cost compared with Embodiment 1 by the cost of mask for printing 3. Soldering paste material filling shown in step S49 is performed by continuing the above-mentioned application. That is, soldering paste material 4 is filled up on bump land 1u between insulating layers 1r.

Then, reflow solder bump formation shown in step S50 is performed. Here, by reflow treatment, heat melting of soldering paste material 4 is performed, and after that solder bump 2 is formed on each bump land 1u by hardening. That is, solder bump 2 is formed by performing heat curing of soldering paste material 4.

Also in the manufacturing method of the semiconductor device of Embodiment 3, by forming insulating layer 1r between each adjoining bump land 1u in a plurality of Cu/Ni wirings 1d which are re-wirings, and then, forming solder bump 2 applying soldering paste material 4 with the printing method on each of a plurality of bump lands 1u, solder bump 2 can be formed without generating the electric short circuit between solder bumps 2 (the short circuit between bumps) even in the case of a narrow pad pitch.

Regarding other effects which are obtained by the manufacturing method of semiconductor device of Embodiment 3, since they are the same as what is explained about the effect which is obtained by the manufacturing method of semiconductor device 5 of Embodiment 1, the duplicate explanation is omitted.

In the foregoing, the present invention accomplished by the present inventors is concretely explained based on above embodiments, but the present invention is not limited by the above embodiments, but variations and modifications may be made, of course, in various ways in the limit that does not deviate from the gist of the invention.

For example, in the above-mentioned Embodiments 1 and 2, for applying soldering paste material 4, the case where it is applied via mask for printing 3 is explained, but when the insulating layer arranged between electrodes is sufficiently hard, it is not necessary to use mask for printing 3.

Although, in the above-mentioned Embodiment 3, the case where soldering paste material 4 is directly applied without using mask for printing 3 is explained, when the hardness of the insulating layer arranged between electrodes is not sufficient, also in the above-mentioned Embodiment 3, soldering paste material 4 may be applied using mask for printing 3.

In the above-mentioned Embodiment 1, although the printing method is explained as a formation method of polyimide film 1i, the formation method is not limited to this and a photo mask may be used to form the film.

The present invention is suitable for the formation technology of a projection electrode, and semiconductor manufacturing technology.

What is claimed is:

1. A semiconductor device comprising:
a semiconductor chip having a main surface, a pad formed on the main surface, and a first insulating film formed on the main surface such that the pad is exposed from the first insulating film;
a second insulating film formed on the first insulating film such that the second insulating film does not cover the pad; and
a solder bump formed on the pad, and formed inside of an area surrounded by the second insulating film such that a part of the solder bump is protruded from a surface of the second insulating film,
wherein the second insulating film contacts with the solder bump;
wherein the second insulating film covers more than half of height of the solder bump; and
wherein the second insulating film is comprised of a polyimide resin.

2. The semiconductor device according to claim 1, wherein a thickness of the second insulating film is larger than that of the first insulating film.
